(19) United States
(12) Patent Application Publication
(10) Pub. No.: US 2026/0033254 A1
(43) Pub. Date: Jan. 29, 2026

(54) HFN-GE-SB-TE PHASE CHANGE MATERIAL AND LOW POWER CONSUMPTION PHASE CHANGE MEMORY

(71) Applicant: HUAZHONG UNIVERSITY OF SCIENCE AND TECHNOLOGY, Hubei (CN)

(72) Inventors: Xiaomin CHENG, Hubei (CN); Siyuan FAN, Hubei (CN); Xiangshui MIAO, Hubei (CN)

(73) Assignee: HUAZHONG UNIVERSITY OF SCIENCE AND TECHNOLOGY, Hubei (CN)

(21) Appl. No.: 19/348,711

(22) Filed: Oct. 2, 2025

Related U.S. Application Data
(63) Continuation of application No. PCT/CN2024/126370, filed on Oct. 22, 2024.

(30) Foreign Application Priority Data
Jan. 4, 2024 (CN) 202410015163.0

(51) Int. Cl. H10N 70/00; H10B 63/10; H10N 70/20

(52) U.S. Cl. CPC H10N 70/8828; H10B 63/10; H10N 70/023; H10N 70/026; H10N 70/063; H10N 70/231; H10N 70/841

(57) ABSTRACT

The disclosure provides an HfN—Ge—Sb—Te phase change material and low power consumption phase change memory, belonging to the field of micro-nano electronics. Its general formula is (HfN)ₓ(Ge-Sb-Te)₁₋ₓ, where x is the percentage of HfN molecules in the total number of molecules. The lattice mismatch between the Ge—Sb—Te based alloy and HfN is greater than 20%, to inhibit the crystalline degree of the Ge—Sb—Te phase change memory material.

### CROSS-REFERENCE TO RELATED APPLICATION

This application is a continuation of international application of PCT application serial no. PCT/CN2024/126370, filed on Oct. 22, 2024, which claims the priority benefit of China application no. 202410015163.0, filed on Jan. 4, 2024. The entirety of each of the above-mentioned patent applications is hereby incorporated by reference herein and made a part of this specification.

### TECHNICAL FIELD

The disclosure belongs to a field of micro-nano electronics, and more specifically, relates to an HfN—Ge—Sb—Te phase change material and a low power consumption phase change memory.

### BACKGROUND TECHNOLOGY

In today's era of rapid development of electronic technology and the information industry, with the explosive growth of data, requirements for the performance of non-volatile memory are becoming increasingly higher. Phase change memory (PCM), with its advantages of high integration, fast response speed, and long cycle life, is considered by the SEMI to be the most likely candidate to replace flash memory and dynamic memory to become the mainstream memory of the future. Phase change memory operates by applying electrical pulses to induce reversible phase transitions between amorphous and crystalline states in the phase change material, storing data as “0” or “1”. A narrow pulse width, high amplitude electric pulse is applied to the unit to perform a RESET operation, where the crystalline phase change memory material melts and rapidly cools to transform into an disordered amorphous state, thus achieving a rapid resistance change from a low resistance state “0” to a high resistance state “1”. Conversely, a wide pulse width, low amplitude electric pulse is applied to the phase change memory unit to perform a SET operation, where the amorphous phase change memory material undergoes an annealing-like process to crystallize, returning to a low resistance state, achieving an erasure of “1” back to “0”. Phase change materials are mainly sulfide compound materials, with compounds composed of Ge, Sb, and Te elements being the most common. Currently, phase change memory has the advantage of being non-volatile, with relatively fast write/erase speeds (tens to hundreds of nanoseconds), but the RESET power consumption is relatively high, which is not conducive to reducing device energy consumption and high integration of memory chips. Further reduction of its RESET power consumption is required.

Optimizing the performance of phase change materials is key to enhancing the performance of phase change memory, and the microstructure of phase change materials determines their macroscopic characteristics. Currently, the main method for optimizing the performance of conventional Ge—Sb—Te phase change materials is doping method. Compared with multi-layer preparation techniques such as pseudo-superlattice and heterogeneous structures, the doping method is simpler, more cost-effective, and more favored by the industry. However, doping method usually improves the crystallization speed, amorphous stability, and other properties of phase change memory, but reports on doping reducing the power consumption of phase change memory are rare. The power consumption of phase change memory is not only related to the melting point of the phase change material but also closely associated with the electrothermal utilization efficiency involving heat generation and dissipation processes within the device. Existing methods for reducing the power consumption of phase change memory mainly include: reducing the contact area between the electrode and the phase change material through device structure design, thereby reducing the phase change region to lower the energy required for phase change; doping with elemental substances such as O to form low thermal conductivity oxide layers within the phase change material, creating local thermal barrier effects and improving energy utilization efficiency. However, these methods also have significant limitations: device structure design does not reduce power consumption from the material's fundamental level, and changes in device structure require modifications to production techniques, resulting in higher costs and greater implementation difficulties, which are challenging to achieve in high-density architectures such as three-dimensional phase change memory; doped elemental substances such as O reacts with other elements in the phase change material leading to phase separation, which could adversely affect other phase change characteristics of the device, such as cycling endurance and crystallization speed.

### SUMMARY OF INVENTION

In view of the deficiencies in the existing technology, the purpose of the disclosure is to provide an HfN—Ge—Sb—Te phase-change material and a low power consumption phase-change memory, addressing the complexity of existing methods for reducing phase-change memory power consumption.

To achieve the above-mentioned purpose, according to one aspect of the disclosure, an HfN—Ge—Sb—Te phase change material is provided, a general formula of which being (HfN)ₓ(Ge—Sb—Te)₁₋ₓ, wherein x represents the percentage of HfN molecules in the total molecule count, and the lattice mismatch between HfN and a crystalline Ge—Sb—Te based alloy is greater than 20%, thereby inhibiting the crystalline degree of the Ge—Sb—Te phase-change material.

As a further preference, the Ge—Sb—Te based alloy could be Ge₂Sb₂Te₅, Ge₁Sb₂Te₄ or Ge₁Sb₄Te₇.

As a further preference, the value range of x is 0<x<30%.

As a further preference, the HfN—Ge—Sb—Te phase change material is in the shape of a thin film, with a thickness of 5 nm to 300 nm.

According to another aspect of the disclosure, a low power consumption phase change memory is provided, which includes a bottom electrode, an isolation layer, a phase change memory material film layer, and a top electrode stacked in sequence, wherein the isolation layer has a through-hole, the phase change memory material film layer is deposited in the through-hole and in contact with the bottom electrode and the top electrode, and the phase change memory material film layer is made of the above-mentioned HfN—Ge—Sb—Te phase change material.

As a further preference, the thickness of the bottom electrode and the top electrode could be 5 nm to 1 μm, a thickness of the phase change memory material film layer is 5 nm to 300 nm, a thickness of the isolation layer is 5 nm to 300 nm, and a diameter of the through-hole in the isolation layer is 10 nm to 1 μm.

As a further preference, a material of the bottom electrode and the top electrode could be Al, Ag, Cu, Ti₃W₇, Pt, Au, W, Ti or TiN, and a material of the isolation layer could be SiO₂, SiC or (ZnS)_{z}(SiO₂)_{100-z}. z is an integer greater than 0 and less than 100.

According to another aspect of the disclosure, a method for preparing the above-mentioned low power consumption phase change memory is provided, which includes the following steps:
S1, preparing the bottom electrode and the isolation layer sequentially on the substrate;
S2, etching the through-hole inside the isolation layer, and the through-hole penetrating the isolation layer to directly contact a surface of the bottom electrode;
S3, depositing the phase change memory material film layer inside the through-hole;
S4, depositing the top electrode on a surface of the phase change memory material film layer, thereby preparing the low power consumption phase change memory.

As a further preference, in step S3, the phase change memory material film layer is prepared by adopting a magnetron sputtering method, a chemical vapor deposition method, an atomic layer deposition method, an electroplating method, or an electron beam evaporation method.

As a further preference, in step S3, when adopting the magnetron sputtering method, the phase change memory material film layer is prepared by adopting a co-sputtering method using an HfN target and a Ge—Sb—Te based alloy target.

Overall, compared with the existing technology, the technical solutions conceived by the disclosure have the following beneficial effects:
1. The disclosure dopes HfN into the Ge—Sb—Te based alloy, and ensures that the lattice mismatch between HfN and the Ge—Sb—Te based alloy is greater than 20%, thereby enabling the HfN—Ge—Sb—Te phase change material to form a more stable amorphous structure, significantly inhibiting its crystalline degree, reducing its crystallization region, and thus improving the amorphous stability of the HfN—Ge—Sb—Te phase change material, inhibiting the resistance drift of the HfN—Ge—Sb—Te phase change material;
2. Meanwhile, the disclosure proposes a low power consumption phase change memory using the aforementioned HfN—Ge—Sb—Te phase change material. It does not require changing the structure of the memory, but only optimizes the composition of the phase change memory material film layer to achieve the function of reducing RESET power consumption. By doping HfN into the Ge—Sb—Te based alloy, the crystalline degree of the phase change material is significantly inhibited, thereby effectively reducing the RESET power consumption of the device, improving the SET speed of the device, and simultaneously inhibiting the resistance drift of the device.

### DESCRIPTION OF DRAWINGS

FIG. 1 is a schematic diagram of the structure of a low power consumption phase change memory provided by an embodiment of the disclosure;

FIG. 2 is an R-T test curve of the phase change material prepared in Embodiment 1, Embodiment 2, and Comparative Example 1 of the disclosure, with a heating rate of 12° C./min;

FIG. 3 is a data retention capability test diagram of the phase change materials prepared in Embodiment 1, Embodiment 2, and Comparative Example 1 of the disclosure;

FIG. 4 is a resistance drift test diagram of the phase change materials prepared in Embodiment 1, Embodiment 2, and Comparative Example 1 of the disclosure, where V in the figure is the resistance drift coefficient;

FIG. 5A is an XRD test pattern of the phase change material prepared in Comparative Example 1 of the disclosure after annealing at 250° C. and 450° C. for 30 minutes;

FIG. 5B is an XRD test pattern of the phase change material prepared in Embodiment 1 of the disclosure after annealing at 250° C. and 450° C. for 30 minutes;

FIG. 6A is a TEM photograph and selected area electron diffraction pattern of the phase change material prepared in Comparative Example 1 of the disclosure after annealing;

FIG. 6B is a TEM photograph and selected area electron diffraction pattern of the phase change material prepared in Embodiment 1 of the disclosure after annealing;

FIG. 7 is a V-R curve of the RESET process for the phase change memory in Comparative Example 2 of the disclosure, with a pulse width of 10 ns;

FIG. 8A is a V-R curve of the SET process where the phase change memory in Comparative Example 2 of the disclosure failed to successfully SET using a 50 ns electric pulse;

FIG. 8B is a V-R curve of the SET process for the phase change memory in Comparative Example 2 of the disclosure, successfully SET using a 60 ns electric pulse;

FIG. 9 is a V-R curve of the RESET process of the phase change memory in Embodiment 3 of the disclosure, with a pulse width of 10 ns;

FIG. 10 is a V-R curve of the SET process for the phase change memory unit in Embodiment 3 of the disclosure, successfully SET using a 10 ns electric pulse;

FIG. 11 is a mean square displacement (MSD) diagram obtained by modeling the phase change material prepared in Comparative Example 1 and Example 1 of the disclosure;

FIG. 12 is a phonon density of states (VDOS) diagram obtained by modeling the phase change material prepared in Comparative Example 1 and Embodiment 1 of the disclosure.

In all drawings, the same reference numerals are used to denote the same elements or structures, wherein: 1—bottom electrode, 2—isolation layer, 3—phase change memory material film layer, 4—top electrode, 5—substrate.

### DETAILED DESCRIPTION OF EMBODIMENTS

In order to make the purpose, technical solution and advantages of the disclosure clearer and more understandable, the following description will provide further detailed explanation of the disclosure in combination with the drawings and embodiments. It should be understood that the specific embodiments described here are only used to explain the disclosure, and are not intended to limit the disclosure.

According to one aspect of the disclosure, an HfN—Ge—Sb—Te phase change material is provided, with a general formula of (HfN)ₓ(Ge—Sb—Te)₁₋ₓ, where x is the percentage of HfN molecules in the total number of molecules, wherein the lattice mismatch between HfN and crystalline Ge—Sb—Te based alloy is greater than 20%, thereby forming a more stable amorphous structure in the HfN—Ge—Sb—Te phase change memory material, inhibiting its crystalline degree and reducing the crystallization region, thus improving the amorphous stability of the HfN—Ge—Sb—Te phase change material and inhibiting its resistance drift.

Further, the Ge—Sb—Te based alloy with a lattice mismatch greater than 20% with HfN could preferably be Ge₂Sb₂Te₅, Ge₁Sb₂Te₄ or Ge₁Sb₄Te₇. By optimizing the selection of the Ge—Sb—Te based alloy, the amorphous stability of the HfN—Ge—Sb—Te phase change material could be further improved.

Further, the range of x is 0<x<30%. When x is too large, HfN could spontaneously form HfN clusters or grains, which cannot utilize its characteristic of large lattice mismatch with the Ge—Sb—Te matrix material to inhibit the crystalline degree of the matrix material.

Furthermore, the HfN—Ge—Sb—Te phase change material could be in the shape of a thin film, with a thickness of 5 nm to 300 nm, ensuring suitability for subsequently practical use.

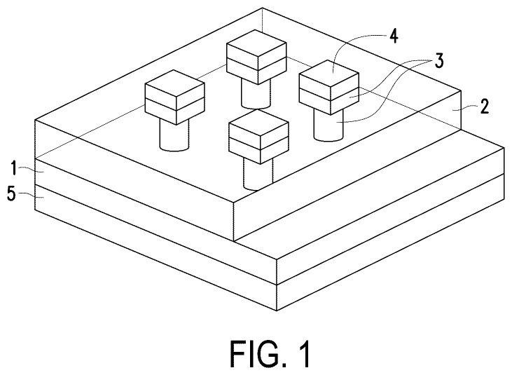

As shown in FIG. 1, according to another aspect of the disclosure, a low power consumption phase change memory is provided, which includes a bottom electrode 1, an isolation layer 2, a phase change memory material film layer 3, and a top electrode 4 stacked in sequence, wherein the isolation layer 2 has a through-hole, the phase change memory material film layer 3 is deposited in the through-hole and in contact with the bottom electrode 1 and the top electrode 4, and the phase change memory material film layer is made of the aforementioned HfN—Ge—Sb-Te phase change material.

Unlike traditional low power consumption phase change memory devices that require significant changes to the device and array structure, the disclosure only improves the material composition of the phase change memory material film layer, achieving low power consumption effects without the need to improve the device and array structure. Specifically, the disclosure significantly inhibits the crystalline degree of Ge—Sb—Te phase change material through doping with HfN, reducing the crystallization region, thereby lowering the RESET power consumption of the device and improving the SET speed of the device. At the same time, doping with HfN forms a more stable amorphous structure in the HfN—Ge—Sb—Te phase change material, improving its amorphous stability and inhibiting resistance drift.

Further, the thickness of the bottom electrode 1 and the top electrode 4 could be 5 nm to 1 μm, the thickness of the phase change memory material film layer 3 could be 5 nm to 300 nm, the thickness of the isolation layer 2 could be 5 nm to 300 nm, and the diameter of the through-hole in the isolation layer 2 could be 10 nm to 1 μm. The material of the bottom electrode 1 and the top electrode 4 could be Al, Ag, Cu, Ti₃W₇, Pt, Au, W, Ti or TiN, and the material of the isolation layer 2 could be SiO₂, SiC or (ZnS)_{z}(SiO₂)_{100-z}, where z is an integer greater than 0 and less than 100.

According to another aspect of the disclosure, a method for preparing the above-mentioned low power consumption phase change memory is provided, which includes the following steps:
S1, preparing a bottom electrode 1 and an isolation layer 2 sequentially on a substrate 5;
S2, etching a through-hole in the isolation layer 2, and the through-hole penetrates the isolation layer 2 and contacts with the surface of the bottom electrode 1;
S3, depositing a phase change memory material film layer 3 inside the through-hole;
S4, depositing a top electrode 4 on the surface of the phase change memory material film layer 3, thereby preparing a low power consumption phase change memory.

Further, in step S3, the phase change memory material film layer could be prepared by magnetron sputtering, chemical vapor deposition, atomic layer deposition, electroplating, or electron beam evaporation. When magnetron sputtering is adopted, the preparation could be conducted through co-sputtering using an HfN target and a Ge—Sb—Te based alloy target.

The technical solution provided by the disclosure will be further explained below according to specific embodiments.

### Embodiment 1

In this embodiment, the prepared HfN—Ge—Sb—Te phase change material has a chemical formula of (HfN)ₓ(Ge₁Sb₄Te₇)₁₋ₓ, where x=0.06. The average bond length of HfN is about 2.2 Å, and the average bond length of Ge₁Sb₄Te₇ is about 3.1 Å. The lattice mismatch rate is approximately 29%, making it impossible for the two to form a lattice match.

(HfN)_{0.06}(Ge₁Sb₄Te₇)_{0.94} is prepared by magnetron sputtering. During preparation, high-purity argon is introduced as the sputtering gas, with a sputtering gas pressure of 0.6 Pa. The Ge₁Sb₄Te₇ target uses a dc power supply with a power of 30 W; the HfN target uses an ac power supply with a power of 15 W. The specific preparation technique includes the following steps:
1. Select a SiO₂/Si substrate (with lattice orientation in the 100 direction) with dimensions of 1 cm×1 cm, clean the surface and back side to remove dust particles, organic and inorganic impurities;
a) Place the SiO₂/Si (lattice oriented in the 100 direction) substrate in acetone solution and vibrate ultrasonically with 40 W power for 10 minutes, then rinse with deionized water;
b) The substrate treated with acetone is vibrated in ethanol solution for 10 minutes with 40 W power ultrasonic vibration, rinsed with deionized water, and the surface and back are blown dry with high purity N₂ gas to obtain the substrate ready for sputtering;
2. Prepare HfN—Ge—Sb—Te phase change material by co-sputtering method using dc and ac power supplies;
a) Place the HfN target material and Ge₁Sb₄Te₇ alloy target material, both with a purity of 99.99% (atomic percentage), and evacuate the chamber to a base vacuum of 10-4 Pa;
b) Use high purity Ar gas as the sputtering gas, adjust the sputtering gas pressure to 0.6 Pa, and set the distance between the target material and the substrate to 120 mm;
c) Set the dc power supply power to 30 W, and the ac power supply power to 15 W;
d) Conduct pre-sputtering for 10 min on the HfN target material and Ge₁Sb₄Te₇ target material to clean the surface of the target materials;
e) After the pre-sputtering is completed, the shutter is opened, and when the sputtering time is 250 s, the thickness of the prepared film is about 100 nm.

### Embodiment 2

In this embodiment, the chemical formula of the prepared HfN—Ge—Sb—Te phase change material is (HfN)ₓ(Ge₁Sb₄Te₇)₁₋ₓ, where x=0.28.

(HfN)_{0.28}(Ge₁Sb₄Te₇)_{0.72} is prepared by magnetron sputtering. During preparation, high-purity argon is introduced as the sputtering gas, with a sputtering gas pressure of 0.6 Pa. The Ge₁Sb₄Te₇ target uses a dc power supply with a power of 30 W; the HfN target uses an ac power supply with a power of 25 W. The specific preparation technique includes the following steps:
1. Select a SiO₂/Si substrate (with lattice orientation in the 100 direction) with dimensions of 1 cm×1 cm, clean the surface and back side to remove dust particles, organic and inorganic impurities;
a) Place the SiO₂/Si (lattice oriented in the 100 direction) substrate in acetone solution and vibrate ultrasonically with 40 W power for 10 minutes, then rinse with deionized water.
b) The substrate treated with acetone is vibrated in ethanol solution for 10 minutes with 40 W power ultrasonic vibration, rinsed with deionized water, and the surface and back are blown dry with high purity N₂ gas to obtain the substrate ready for sputtering.
2. Prepare HfN—Ge—Sb—Te phase change material by co-sputtering method using dc and ac power supplies;
a) Place the HfN target material and Ge₁Sb₄Te₇ alloy target material, both with a purity of 99.99% (atomic percentage), and evacuate the chamber to a base vacuum of 10-4 Pa;
b) Use high purity Ar gas as the sputtering gas, adjust the sputtering gas pressure to 0.6 Pa, and set the distance between the target material and the substrate to 120 mm;
c) Set the dc power supply power to 30 W, and the ac power supply power to 25 W;
d) Conduct pre-sputtering for 10 min on the HfN target material and Ge₁Sb₄Te₇ target material to clean the surface of the target materials;
e) After the pre-sputtering is completed, the shutter is opened, and when the sputtering time is 250 s, the thickness of the prepared film is about 100 nm.

### Comparative Example 1

In this comparative example, pure Ge₁Sb₄Te₇ phase change material is prepared.

Pure Ge₁Sb₄Te₇ phase change material is prepared by sputtering method. During preparation, high purity argon gas is introduced as the sputtering gas, with a sputtering gas pressure of 0.6 Pa. The Ge₁Sb₄Te₇ target is sputtered using a dc power supply with a power of 30 W.

The specific preparation technique includes the following steps:
1. Select a SiO₂/Si substrate (with lattice orientation in the 100 direction) with dimensions of 1 cm×1 cm, clean the surface and back side to remove dust particles, organic and inorganic impurities;
a) Place the SiO₂/Si (lattice oriented in the 100 direction) substrate in acetone solution and vibrate ultrasonically with 40 W power for 10 minutes, then rinse with deionized water;
b) The substrate treated with acetone is vibrated in ethanol solution for 10 minutes with 40 W power ultrasonic vibration, rinsed with deionized water, and the surface and back are blown dry with high purity N₂ gas to obtain the substrate ready for sputtering;
2. Prepare pure Ge₁Sb₄Te₇ phase change memory material film using dc power supply sputtering method;
a) Place the Ge₁Sb₄Te₇ alloy target material with a purity of 99.99% (atomic percentage), and evacuate its base vacuum to 10⁴ Pa;
b) Use high purity Ar gas as the sputtering gas, adjust the sputtering gas pressure to 0.6 Pa, and set the distance between the target material and the substrate to 120 mm;
c) Set the dc power supply power to 30 W;
d) Conduct pre-sputtering on the Ge₁Sb₄Te₇ target material for 10 min to clean the surface of the target material;
e) After the pre-sputtering is completed, the shutter is opened, and when the sputtering time is 250 s, the thickness of the prepared material film is about 100 nm.

Conduct tests on the phase change materials in Embodiment 1, Embodiment 2, and Comparative Example 1.

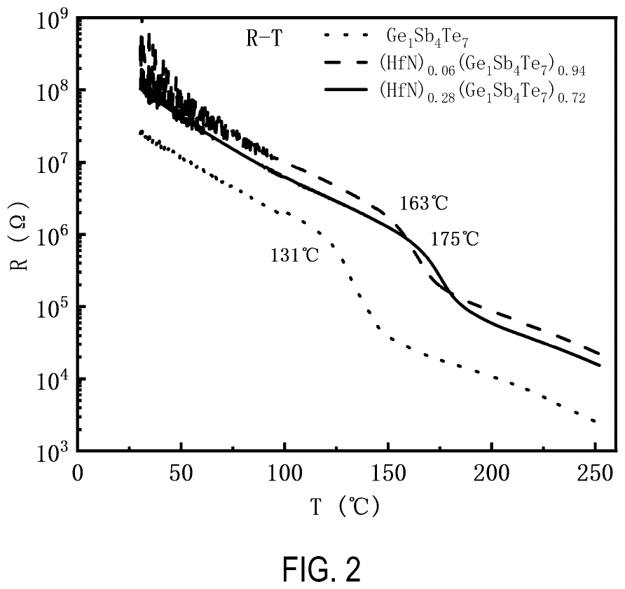

FIG. 2 is an R-T test curve of the phase change materials in Embodiment 1, Embodiment 2, and Comparative Example 1, with a heating rate of 12° C./min. The crystallization temperatures of pure Ge₁Sb₄Te₇, (HfN)_{0.06}(Ge₁Sb₄Te₇)_{0.94} and (HfN)_{0.28}(Ge₁Sb₄Te₇)_{0.72} are 131° C., 163° C. and 175° C., respectively. By comparison, it could be seen that HfN doping improves the crystallization temperature of the film, thereby improving the amorphous stability of the HfN—Ge—Sb—Te phase change material.

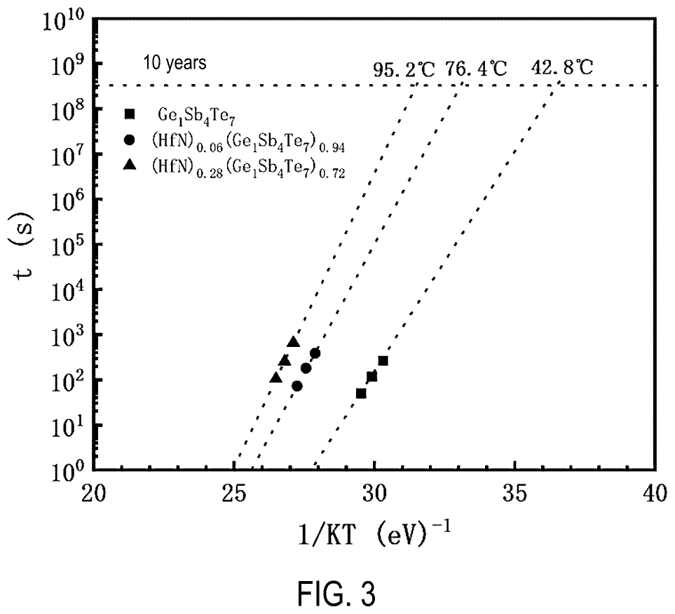

FIG. 3 is a data retention capability test diagram of the phase change materials in Embodiment 1, Embodiment 2, and Comparative Example 1. By comparison, it can be seen that HfN doping improved the ten-year data retention temperature of HfN—Ge—Sb—Te phase change material. The ten-year data retention temperatures of pure Ge₁Sb₄Te₇, (HfN)_{0.06}(Ge₁Sb₄Te₇)_{0.94} and (HfN)_{0.28}(Ge₁Sb₄Te₇)_{0.72} films are 42.8° C., 76.4° C. and 95.2° C., respectively. The ten-year data retention temperature increases with the increase of HfN doping amount, which further verifies that HfN doping is beneficial to improve the amorphous stability of Ge—Sb—Te phase change material.

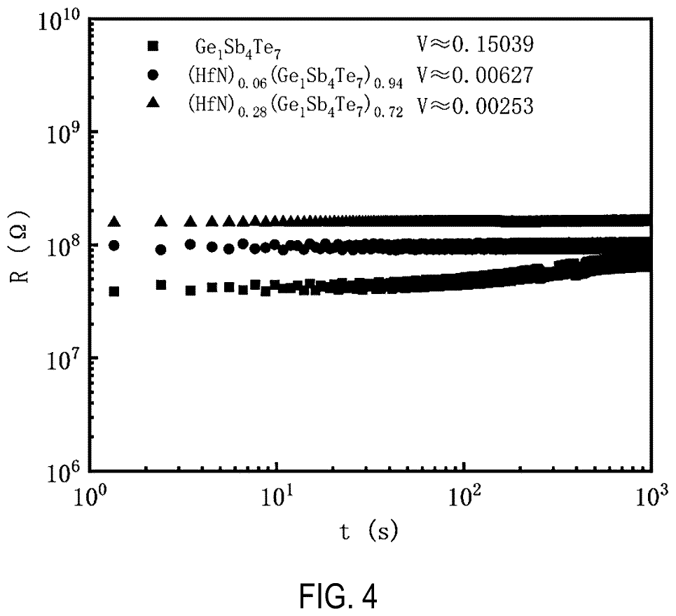

FIG. 4 is a resistance drift test diagram of the phase change materials in Embodiment 1, Embodiment 2, and Comparative Example 1. By comparison, it can be seen that HfN doping significantly reduces the resistance drift coefficient of HfN—Ge—Sb—Te phase change material. The resistance drift coefficients of pure Ge₁Sb₄Te₇, (HfN)_{0.06}(Ge₁Sb₄Te₇)_{0.94} and (HfN)_{0.28}(Ge₁Sb₄Te₇)_{0.72} are 0.15039, 0.00627, and 0.00253, respectively. The reduction in resistance drift coefficient is beneficial for maintaining stable resistance states in phase change memory.

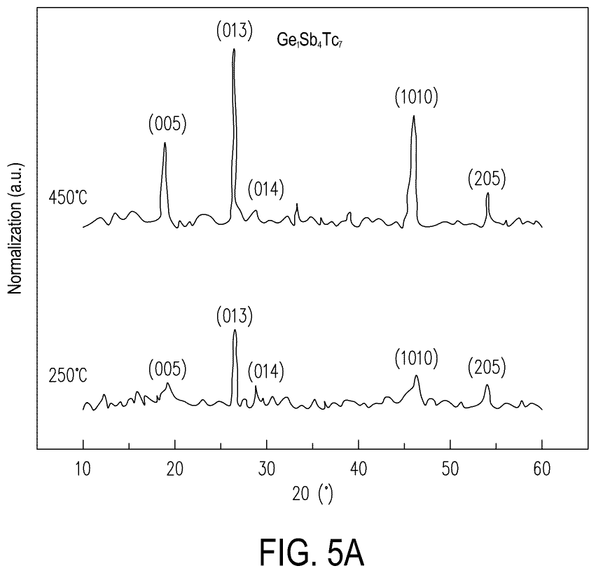

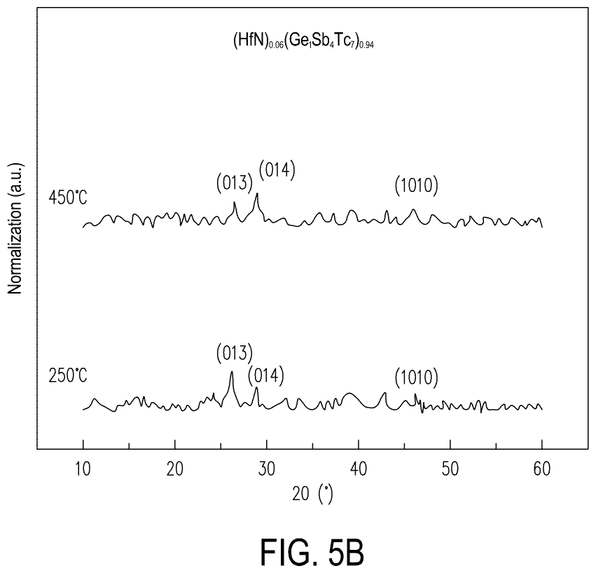

FIG. 5A and FIG. 5B are XRD test diagrams of phase change materials in Comparative Example 1 and Embodiment 1, respectively. HfN doping significantly reduces the diffraction peak intensity of Ge₁Sb₄Te₇ after annealing. With further increase in annealing temperature, the diffraction peak intensity of Ge₁Sb₄Te₇ remains very low, indicating that HfN doping inhibits the crystalline degree of the HfN—Ge—Sb—Te phase change material.

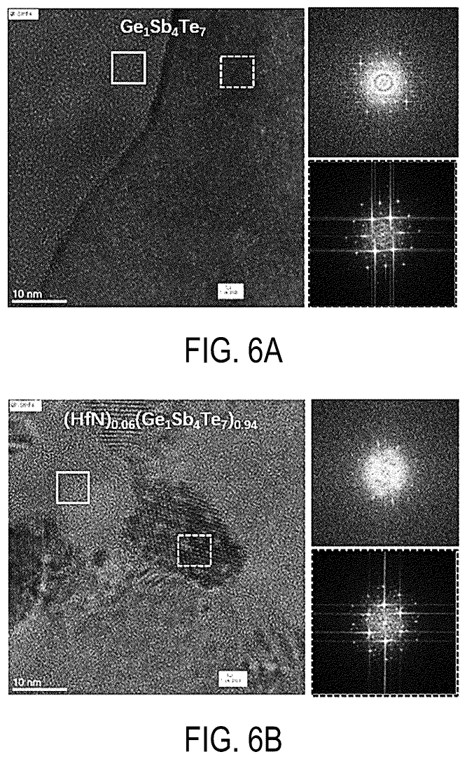

FIG. 6A and FIG. 6B are TEM photographs and selected area electron diffraction patterns of the phase change material films after annealing in Comparative Example 1 and Embodiment 1, respectively. The crystalline degree in pure Ge₁Sb₄Te₇ is very high, with all regions being single crystals or polycrystals with a very high crystalline degree, while in (HfN)_{0.06}(Ge₁Sb₄Te₇)_{0.94}, part of the region is in a crystalline state and another part is in an amorphous state. Overall, the crystalline degree of the (HfN)_{0.06}(Ge₁Sb₄Te₇)_{0.94} thin film after annealing is lower than that of pure Ge₁Sb₄Te₇, further verifying the inhibitory effect of HfN doping on the crystalline degree of HfN—Ge—Sb—Te phase change material.

### Embodiment 3

In this embodiment, (HfN)_{0.06}(Ge₁Sb₄Te₇)_{0.94} from Embodiment 1 is adopted as the phase change memory material to prepare the phase change memory, wherein the phase change memory material film layer 3 is prepared by magnetron sputtering. During preparation, high-purity argon is introduced as the sputtering gas, with a sputtering gas pressure of 0.6 Pa. The Ge₁Sb₄Te₇ target uses a dc power supply with a power of 30 W; the HfN target uses an ac power supply with a power of 15 W. The specific preparation technique includes the following steps:
1. Select a SiO₂/Si substrate (with lattice orientation in the 100 direction) with dimensions of 1 cm×1 cm, clean the surface and back side to remove dust particles, organic and inorganic impurities;
a) Place the SiO₂/Si (lattice oriented in the 100 direction) substrate in acetone solution and vibrate ultrasonically with 40 W power for 10 minutes, then rinse with deionized water;
b) The substrate treated with acetone is vibrated in ethanol solution for 10 minutes with 40 W power ultrasonic vibration, rinsed with deionized water, and the surface and back are blown dry with high purity N₂ gas to obtain the substrate ready for sputtering;
2. Prepare a 100 nm Pt bottom electrode using a dc power supply sputtering method;
3. Deposit a 100 nm SiO₂ insulating layer on the Pt bottom electrode by chemical vapor deposition;
4. Through electron beam lithography etching and other techniques, through-holes with a depth of 100 nm and a diameter of 250 nm is formed in the SiO₂ insulating layer;
5. Form a memory array through photolithography technique;
6. Adopt a co-sputtering method using both dc and ac power supplies to fill (HfN)_{0.06}(Ge₁Sb₄Te₇)_{0.94} phase change memory film material in the through-hole;
a) Place the HfN target material and Ge₁Sb₄Te₇ alloy target material, both with a purity of 99.99% (atomic percentage), and evacuate the chamber to a base vacuum of 10-4 Pa;
b) Use high purity Ar gas as the sputtering gas, adjust the sputtering gas pressure to 0.6 Pa, and set the distance between the target material and the substrate to 120 mm;
c) Set the dc power supply power to 30 W, and the ac power supply power to 15 W;
d) Conduct pre-sputtering for 10 min on the HfN target material and Ge₁Sb₄Te₇ target material to clean the surface of the target materials;
e) After the pre-sputtering is completed, the shutter is opened, and when the co-sputtering time is 250 s, the prepared phase change layer has a thickness of about 100 nm;
7. A low power consumption phase change memory with a complete (HfN)_{0.06}(Ge₁Sb₄Te₇)_{0.94} phase change layer is prepared by sputtering a 100 nm Pt top electrode using a dc power supply method.

### Comparative Example 2

In this comparative example, a memory device is prepared using pure Ge₁Sb₄Te₇ phase change material from Comparative Example 1 as the material for the phase change memory material film layer. The Ge₁Sb₄Te₇ phase change layer is prepared by magnetron sputtering. This Comparative Example 2 forms a control group with the device prepared in Embodiment 3, with the only difference being whether the phase change layer material is doped or not, while all other device structures, materials, and preparation techniques are the same as in Embodiment 3. During preparation, high-purity argon is introduced as the sputtering gas, with a sputtering gas pressure of 0.6 Pa. The Ge₁Sb₄Te₇ target uses a dc power supply with a power of 30 W. The specific preparation technique includes the following steps:
1. Select a SiO₂/Si substrate (with lattice orientation in the 100 direction) with dimensions of 1 cm×1 cm, clean the surface and back side to remove dust particles, organic and inorganic impurities;
a) Place the SiO₂/Si (lattice oriented in the 100 direction) substrate in acetone solution and vibrate ultrasonically with 40 W power for 10 minutes, then rinse with deionized water;
b) The substrate treated with acetone is vibrated in ethanol solution for 10 minutes with 40 W power ultrasonic vibration, rinsed with deionized water, and the surface and back are blown dry with high purity N₂ gas to obtain the substrate ready for sputtering;
2. Prepare a 100 nm Pt bottom electrode using a dc power supply sputtering method;
3. Deposit a 100 nm SiO₂ insulating layer on the Pt bottom electrode by chemical vapor deposition;
4. Through electron beam lithography etching and other techniques, through-holes with a depth of 100 nm and a diameter of 250 nm is formed in the SiO₂ insulating layer;
5. Form a memory array through photolithography technique;
6. Adopt a dc power supply sputtering method to fill Ge₁Sb₄Te₇ phase change memory material film in the through-hole;
a) Place the Ge₁Sb₄Te₇ alloy target material, with a purity of 99.99% (atomic percentage) for all elements, and evacuate the chamber to a base vacuum of 10⁴ Pa;
b) Use high purity Ar gas as the sputtering gas, adjust the sputtering gas pressure to 0.6 Pa, and set the distance between the target material and the substrate to 120 mm;
c) Set the dc power supply power to 30 W;
d) Conduct pre-sputtering on the Ge₁Sb₄Te₇ target material for 10 min to clean the surface of the target material;
e) After the pre-sputtering is completed, the shutter is opened, and when the sputtering time is 250 s, the thickness of the prepared phase change layer is about 100 nm;
7. A 100 nm Pt top electrode is prepared by dc power supply sputtering method to obtain a complete Ge₁Sb₄Te₇ phase change layer phase change memory array.

Conduct electrical performance tests on the phase change memory devices in Embodiment 3 and Comparative Example 2.

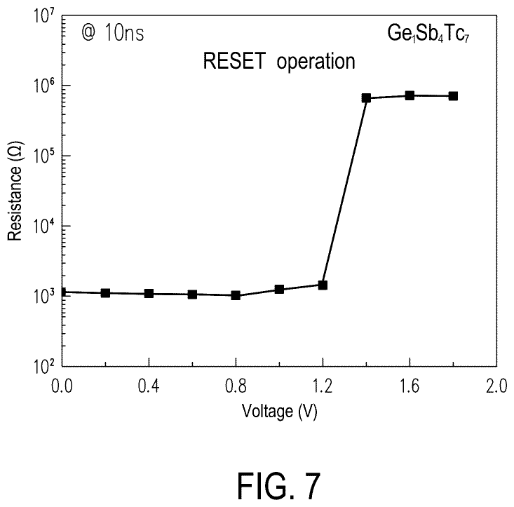

FIG. 7 shows the V-R curve of the RESET process for the Ge₁Sb₄Te₇ phase change memory in Comparative Example 2, with a pulse width of 10 ns. The RESET power consumption is calculated using the formula W=U²/R*t, where U is the voltage at which the resistance jumps to a high value, R is the resistance one step before the resistance jump, and t is the pulse width. The calculated RESET power consumption is 14 pJ.

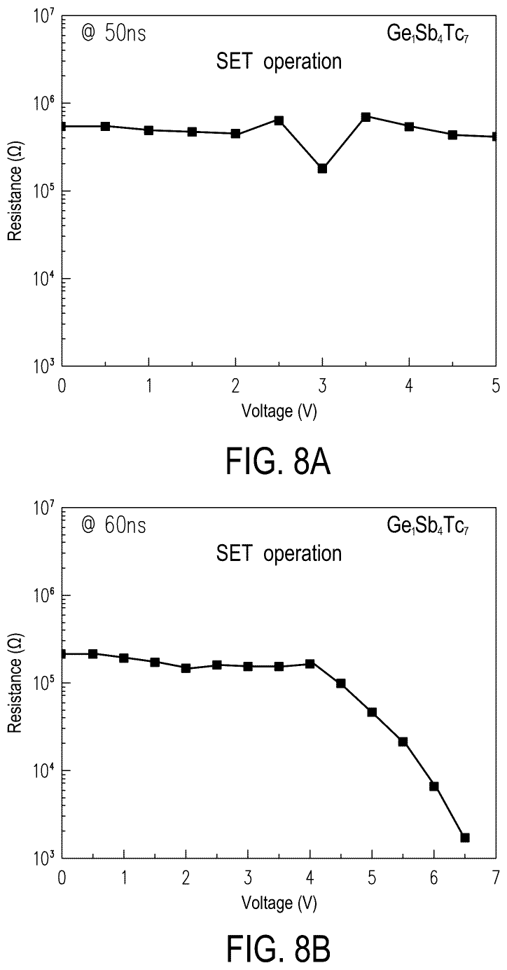

FIG. 8A and FIG. 8B show the V-R curves of the SET process for the Ge₁Sb₄Te₇ phase change memory in Comparative Example 2. FIG. 8A illustrates an unsuccessful SET using a 50 ns electric pulse, while FIG. 8B demonstrates a successful SET using a 60 ns electric pulse. From this, it could be determined that the SET speed of the pure Ge₁Sb₄Te₇ phase change memory is 60 ns.

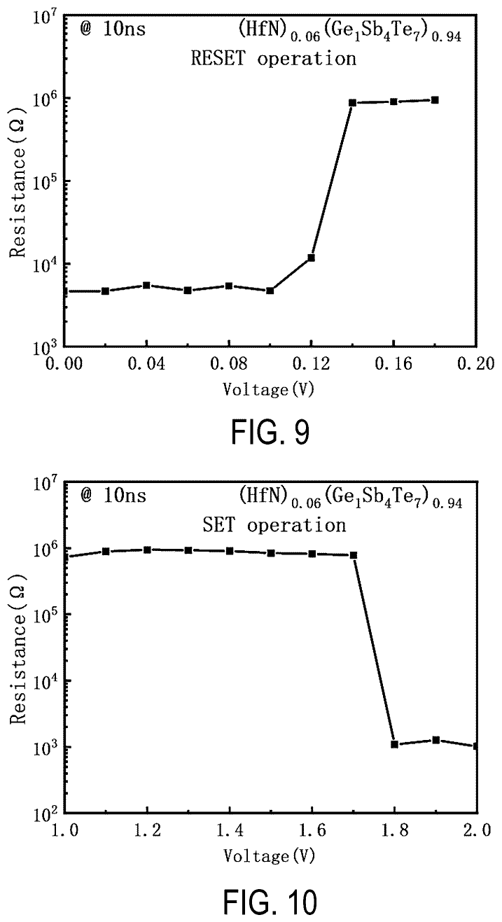

FIG. 9 is a V-R curve of the RESET process for the (HfN)_{0.06}(Ge₁Sb₄Te₇)_{0.94} phase change memory in Embodiment 3, with a pulse width of 10 ns. The RESET power consumption is calculated using the formula W=U²/R*t, where U is the voltage at which the resistance jumps to high resistance, R is the resistance one step before the resistance jump, and t is the pulse width. The calculated RESET power consumption of the (HfN)_{0.06}(Ge₁Sb₄Te₇)_{0.94} phase change memory is 17 fJ, which is much lower than the RESET power consumption of the pure Ge₁Sb₄Te₇ phase change memory in Comparative Example 2.

FIG. 10 is a V-R curve of the SET process for the (HfN)_{0.06}(Ge₁Sb₄Te₇)_{0.94} phase change memory unit in Embodiment 3, which is successfully SET using a 10 ns electric pulse. Therefore, the SET speed of the HfN-doped Ge₁Sb₄Te₇ phase change memory is faster than that of the pure Ge₁Sb₄Te₇ phase change memory. HfN doping could effectively improve the SET speed of the Ge—Sb—Te phase change memory.

Using the Materials Studio software, modeling is conducted for pure Ge₁Sb₄Te₇ in Comparative Example 1 and (HfN)_{0.06}(Ge₁Sb₄Te₇)_{0.94} in Embodiment 1. First-principles calculations are used to simulate the relaxation, melting, and quenching processes for both models to obtain the amorphous models of pure Ge₁Sb₄Te₇ and (HfN)_{0.06}(Ge₁Sb₄Te₇)_{0.94}.

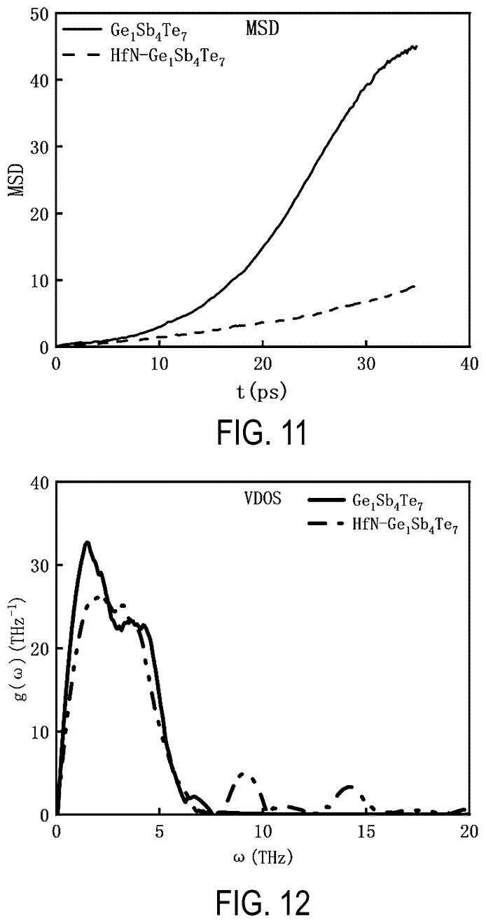

FIG. 11 shows the mean square displacement (MSD) images obtained after molecular dynamics simulation at 300K for two groups of amorphous models. The mean square displacement calculation of the amorphous models at 300K reflects the spontaneous changes and displacement of the internal atomic structure of the material at room temperature. The results show that the mean square displacement of the (HfN)_{0.06}(Ge₁Sb₄Te₇)_{0.94} model is significantly reduced, which is beneficial for inhibiting the drift of its amorphous resistance.

FIG. 12 shows the vibrational density of states (VDOS) images obtained after 300K molecular dynamics simulation of two amorphous models. The amorphous model has fewer vibration modes in the low frequency region and more vibration modes in the high frequency region, which means stronger amorphous stability. The results show that compared with the pure Ge₁Sb₄Te₇ model, the (HfN)_{0.06}(Ge₁Sb₄Te₇)_{0.94} model has reduced vibration modes in the low frequency region and new vibration modes appear in the high frequency region, theoretically verifying that (HfN)_{0.06}(Ge₁Sb₄Te₇)_{0.94} has better amorphous stability.

In the above embodiments and comparative examples, the base material is all adopted as Ge₁Sb₄Te₇. In specific embodiments, other component ratios of Ge—Sb—Te base materials could also be adopted, such as Ge₂Sb₂Te₅, Ge₁Sb₂Te₄, etc., as long as the lattice mismatch between HfN and crystalline Ge—Sb—Te based alloy is greater than 20%. This could achieve the purpose of the disclosure to use HfN doping to inhibit the crystalline degree of Ge—Sb—Te base material and reduce the crystallization region, thereby improving the amorphous stability of the base phase change material and inhibiting its resistance drift. This ultimately provides the technical effect of reducing the RESET power consumption of the phase change memory device.

The average bond length of HfN is about 2.2 Å, and the average bond length of Ge₂Sb₂Te₅ is about 3.0 Å, with a lattice mismatch rate of approximately 27% between the two. The average bond length of Ge₁Sb₂Te₄ is about 3.1 Å, and the lattice mismatch rate between HfN and Ge₁Sb₂Te₄ is approximately 29%. Therefore, in the specific embodiment of the disclosure, Ge₂Sb₂Te₅ and Ge₁Sb₂Te₄ could also be adopted as the matrix phase change material.

Compared with the undoped Ge—Sb—Te system phase change memory materials and devices in the existing technology, in the disclosure's HfN—Ge—Sb—Te phase change materials and devices, HfN doping significantly inhibits the crystalline degree of the crystalline Ge—Sb—Te phase change material, reduces the crystallization region, thereby lowering the RESET power consumption of the device, and improves the SET speed of the device; meanwhile, HfN doping also makes the amorphous structure of Ge—Sb—Te phase change material more stable, improves the amorphous stability of the material and device, and inhibits the resistance drift of the material and device.

Those skilled in the art could easily understand that the above description is only a preferred embodiment of the disclosure and is not intended to limit the disclosure. Any modifications, equivalent substitutions, and improvements made within the spirit and principles of the disclosure should be included in the protection scope of the disclosure.

What is claimed is:

1. An HfN—Ge—Sb—Te phase change material, wherein a general formula of the HfN—Ge—Sb-Te phase change material is (HfN)ₓ(Ge—Sb—Te)₁₋ₓ, and x is a percentage of an HfN molecule number in a total molecule number, wherein a lattice mismatch between HfN and a crystalline Ge—Sb—Te based alloy is greater than 20% to inhibit a crystalline degree of a Ge—Sb—Te phase change material.

2. The HfN—Ge—Sb—Te phase change material according to claim 1, wherein the Ge—Sb—Te based alloy is Ge₂Sb₂Te₅, Ge₁Sb₂Te₄ or Ge₁Sb₄Te₇.

3. The HfN—Ge—Sb—Te phase change material according to claim 1, wherein a value range of x is 0<x<30%.

4. The HfN—Ge—Sb—Te phase change material according to claim 1, wherein the HfN—Ge—Sb—Te phase change material is in a thin film shape with a thickness of 5 nm to 300 nm.

5. A low power consumption phase change memory, wherein the low power consumption phase change memory comprises a bottom electrode, an isolation layer, a phase change memory material film layer and a top electrode sequentially stacked, wherein the isolation layer has a penetrating through-hole, the phase change memory material film layer is deposited in the through-hole and contacts the bottom electrode and the top electrode, and the phase change memory material film layer is made of the above HfN—Ge—Sb—Te phase change material.

6. The low power consumption phase change memory according to claim 5, wherein a thickness of the bottom electrode and the top electrode is 5 nm to 1 μm, a thickness of the phase change memory material film layer is 5 nm to 300 nm, a thickness of the isolation layer is 5 nm to 300 nm, and a diameter of the through-hole in the isolation layer is 10 nm to 1 μm.

7. The low power consumption phase change memory according to claim 5, wherein a material of the bottom electrode and the top electrode is Al, Ag, Cu, Ti₃W₇, Pt, Au, W, Ti or TiN, and a material of the isolation layer is SiO₂, SiC or (ZnS)_{z}(SiO₂)_{100-z}, wherein z is an integer greater than 0 and less than 100.

8. A method for preparing the low power consumption phase change memory according to claim 5, wherein the method comprises the following steps:
S1, preparing the bottom electrode and the isolation layer sequentially on a substrate;
S2, etching the through-hole in the isolation layer, the through-hole penetrating the isolation layer to reach a surface of the bottom electrode;
S3, depositing the phase change memory material film layer inside the through-hole;
S4, depositing the top electrode on a surface of the phase change memory material film layer, thereby preparing the low power consumption phase change memory.

9. The method for preparing the low power consumption phase change memory according to claim 8, wherein, in the step S3, the phase change memory material film layer is prepared by adopting a magnetron sputtering method, a chemical vapor deposition method, an atomic layer deposition method, an electroplating method, or an electron beam evaporation method.

10. The method for preparing the low power consumption phase change memory according to claim 9, wherein, in the step S3, when adopting the magnetron sputtering method, the phase change memory material film layer is prepared by adopting a co-sputtering method using an HfN target and a Ge—Sb—Te based alloy target.
